(19) United States
(12) Patent Application Publication
(10) Pub. No.: US 2011/0101393 A1
(43) Pub. Date: May 5, 2011

(54) LIGHT-EMITTING DIODE PACKAGE STRUCTURE AND MANUFACTURING METHOD THEREOF

(75) Inventors: Chin-Yuan Hsu, Taipei (TW); Chia-Hsien Chang, Taipei (TW)

(73) Assignee: EVERLIGHT ELECTRONICS CO., LTD., Taipei (TW)

(21) Appl. No.: 12/703,744

(22) Filed: Feb. 10, 2010

(30) Foreign Application Priority Data
Nov. 4, 2009 (TW) 98137456

(51) Int. Cl. H01L 33/00; H01L 21/60

(52) U.S. Cl. 257/98; 257/99; 438/26; 257/E33.066; 257/E33.068; 257/E21.509

(57) ABSTRACT

A light-emitting diode (LED) package structure includes a LED chip, an interconnecting substrate, a first conductive lead and a second conductive lead. The LED chip is provided with first and second electrical contacts formed on the same side thereof. The upper surface of the interconnecting substrate is provided with two conductive traces and first, second, third and fourth conductive pads. The first and second conductive pads are electrically connected to the third and fourth conductive pads by the two conductive traces, respectively. The first and second conductive leads are directly soldered to the third and fourth conductive pads, respectively. The LED chip is mounted onto the upper surface of the interconnecting substrate in a flip-chip configuration so that the first and second conductive pads thereof are mechanically and electrically connected to the first and second electrical contacts, respectively.

### CROSS-REFERENCE TO RELATED APPLICATION

This application claims the priority benefit of Taiwan application serial No. 98137456, filed on Nov. 4, 2009. The entirety of the above-mentioned patent application is hereby incorporated by reference herein and made a part of this specification.

### BACKGROUND OF THE INVENTION

1. Field of the Invention

The present invention relates to a light-emitting diode (LED) package structure and manufacturing method thereof and, more particularly, to a LED package structure without using the wire bonding to connect with the electrode and a manufacturing method thereof.

2. Description of Related Art

Due to good electrical characteristics of low power consumption, low heat emission, long lifetime, impact endurance, small volume, high speed of response, can emit the light with stable wavelength and so forth, LEDs have been extensively applied in various home appliances, instruments as indicators, light sources in electrical-optical product and optical communication system.

The conventional LED package structure needs to perform the wire bonding process so as to electrically connect to the LED chip and the lead frame.

However, it needs to reserve the wire space in the above-mentioned LED device, hence the whole size of the LED device will be limited and the miniaturization of the size of the LED device is unfavorable.

### SUMMARY OF THE INVENTION

Hence, the object of the present invention is to provide a light-emitting diode (LED) package structure and manufacturing method thereof to overcome or improve the problems associated with prior art techniques.

According to an aspect of the present invention, a LED package structure includes an interconnecting substrate, a first conductive trace, a second conductive trace, a first conductive pad, a third conductive pad, a second conductive pad, a fourth conductive pad, a LED chip, a first conductive lead and a second conductive lead. The interconnecting substrate has an upper surface and a lower surface. The first conductive trace and the second conductive trace are disposed on the upper surface of the interconnecting substrate. The first conductive pad and the third conductive pad are directly disposed on the first conductive trace and electrically connected to each other. The second conductive pad and the fourth conductive pad are directly disposed on the second conductive trace and electrically connected to each other. The LED chip has a first electrical contact and a second contact, wherein the LED chip is mounted onto the upper surface of the interconnecting substrate in a flip-chip configuration so that the first conductive contact and the second conductive contact are mechanically and electrically connected to the first electrical pad and the second electrical pad of the interconnecting substrate, respectively. The first conductive lead and the second conductive lead are respectively soldered on the third conductive pad and the fourth conductive pad.

According to another aspect of the present invention, a LED package structure includes an interconnecting substrate, two plating through holes (PTH), a first conductive pad, a third conductive pad, a second conductive pad, a fourth conductive pad, a LED chip, a first conductive lead and a second conductive lead. The plating through holes are disposed in the interconnecting substrate. The first conductive pad and the third conductive pad are directly disposed in one of the plating through holes and electrically connected to each other. The second conductive pad and the fourth conductive pad are directly disposed in the other one plating through holes and electrically connected to each other. The LED chip has a first electrical contact and a second contact, wherein the LED chip is mounted onto the upper surface of the interconnecting substrate in a flip-chip configuration so that the first conductive contact and the second conductive contact are mechanically and electrically connected to the first electrical pad and the second electrical pad of the interconnecting substrate, respectively. The first conductive lead and the second conductive lead are respectively soldered on the third conductive pad and the fourth conductive pad.

The first electrical contact and the second electrical contact of the above-mentioned LED chip are mechanically and electrically connected to the first conductive pad and the second conductive pad of the interconnecting substrate via two metal joints.

Since the LED package structure of the present invention does not need to perform the wire bonding step so as to simplify the package structure and the process.

### BRIEF DESCRIPTION OF THE DRAWINGS

In order to make the above and other objects, features and advantages of the present invention more comprehensible, several embodiments accompanied with figures are described in detail below.

FIG. 1 is a schematic cross-sectional view depicting a light-emitting diode (LED) package structure according to an embodiment of the present invention.

FIG. 2 is a schematic cross-sectional view depicting a light-emitting diode (LED) package structure according to another embodiment of the present invention.

### DESCRIPTION OF EMBODIMENTS

Although the present invention may be embodied in many different forms, the embodiments accompanied with figures and the below general descriptions are only for explanation and presented as examples, but not intended to limit the figures/descriptions of the invention.

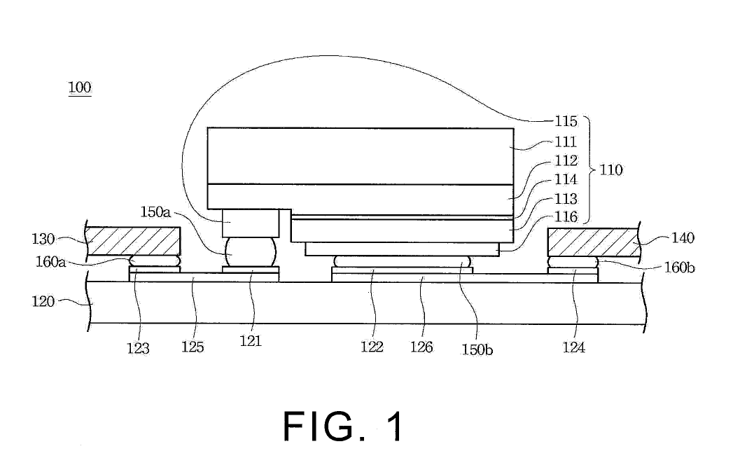

FIG. 1 is a schematic view of an LED package structure 100 according to an embodiment of the present invention, wherein the LED package structure 100 includes a LED chip 110, an interconnecting substrate 120, a first conductive lead 130 and a second conductive lead 140.

An upper surface of the interconnecting substrate 120 is provided with two conductive traces 125, 126. A first conductive pad 121 and a third conductive pad 123 are disposed on the conductive trace 125, and the first conductive pad 121 and the third conductive pad 123 are electrically connected to each other. A second conductive pad 122 and a fourth conductive pad 124 are disposed on the conductive trace 126, and the second conductive pad 122 and the fourth conductive pad 124 are electrically connected to each other.

The interconnecting substrate 120 as described above has good thermal conductivity and is made of the electrical insulating materials so as to carry the LED chip 110 and improve the effect of the heat-dissipation. The suitable material of the interconnecting substrate 120 in the present invention comprises, for example but not limited to, ceramic, aluminum oxide(Al₂O₃), aluminum nitride(AlN), silicon(Si) and gallium arsenide(GaAs). The conductive traces 125,126 as described above are, for example, copper wiring, and the material of the first conductive pad 121, the second conductive pad 122, the third conductive pad 123 and the fourth conductive pad 124 as described above is, for example, gold (Au) or palladium (Pd).

In some embodiments, the first conductive pad 121, the second conductive pad 122, the third conductive pad 123 and the fourth conductive pad 124 as described above are directly formed with a portion of the conductive traces 125 and 126.

The LED chip 110 as described above includes a substrate 111, a first electrical semiconductor layer 112, an active layer 114 and a second electrical semiconductor layer 113 from top to bottom. In addition, the LED chip 110 further includes a first electrical contact 115 and a second electrical contact 116 formed on the same side of the LED chip 110. Herein, the first electrical contact 115 is electrically connected to the first electrical semiconductor layer 112, and the second electrical contact 116 is electrically connected to the second semiconductor layer 113.

The material of the substrate 111 as described above is, for example, a transparent glass such as sapphire, silicon carbide (SiC), gallium nitride (GaN), glass and so forth. The material of the above-mentioned first electrical semiconductor layer 112 is, for example, N-type AlInGaP. The active layer 114 is, for example, multiple quantum well (MQW) structure made of the AlInGaP. The material of the second electrical semiconductor layer 113 is, for example, P-type AlInGaP. The material of the above-mentioned first electrical contact 115 can be, for example, In, Al, Ti, Au, W, InSn, TiN, WSi, PtIn₂, Nd/Al, Ni/Si, Pd/Al, Ta/Al, Ti/Ag, Ta/Ag, Ti/Al, Ti/Au, Ti/TiN, Zr/ZrN, Au/Ge/Ni, Cr/Ni/Au, Ni/Cr/Au, Ti/Pd/Au, Ti/Pt/Au, Ti/Al/Ni/Au, Au/Si/Ti/Au/Si, Au/Ni/Ti/Si/Ti or a combination of alloys thereof. The material of the second electrical contact 116 can be, for example, Ni/Au, NiO/Au, Pd/Ag/Au/Ti/Au, Pt/Ru, Ti/Pt/Au, Pd/Ni, Ni/Pd/Au, Pt/Ni/Au, Ru/Au, Nb/Au, Co/Au, Pt/Ni/Au, Ni/Pt, NiIn, Pt₃In₇ or a combination of alloys thereof.

Referring to FIG. 1, the LED chip 110 is mounted onto the upper surface of the interconnecting substrate 120 in a flip-chip configuration, and the first electrical contact 115 and the second electrical contact 116 of the LED chip 110 are mechanically and electrically connected to the first conductive pad 121 and the second conductive pad 122 disposed on the upper surface of the interconnecting substrate 120 via two metal joints 150a and 150b. The above-mentioned metal joints 150a and 150b are, for example, solder joints or gold stud bumps.

The first conductive lead 130 and the second conductive lead 140 as described above are respectively soldered on the third conductive pad 123 and the fourth conductive pad 124 by using the solder joints 160a and 160b.

The LED package structure 100 as described above utilizes the transparent encapsulant to perform the packaging process. The packaged LED is connected to, for example, a external device such as a substrate, a printed circuit board (PCB) and so forth by the external connecting portion such as the first conductive lead 130, the second conductive lead 140 and so forth. In operating the LED package structure 100, electric power is applied to the second conductive lead 140 (the second electrical contact 116 is P-type).

In some embodiment, the second electrical contact 116 has a high reflectivity (for example more than 70%) to reflect the light from the upper surface of the substrate 111. The material of the higher-reflectivity second electrical contact 116 is, for example, titanium, gold, aluminum, silver, platinum, palladium or a combination of alloys thereof.

The above-mentioned LED package structure 100 can be fabricated by the following packaging process. Firstly, the LED chip 110 is mounted onto the upper surface of the interconnecting substrate 120 in a flip-chip configuration so that the first conductive contact 115 and the second conductive contact 116 are mechanically and electrically connected to the first electrical pad 121 and the second electrical pad 122, respectively. Next, the first conductive lead 130 and the second conductive lead 140 are respectively soldered on the third conductive pad 123 and the fourth conductive pad 124. In other embodiments, the first conductive lead 130 and the second conductive lead 140 may also be respectively soldered on the third conductive pad 123 and the fourth conductive pad 124 at first, and then the LED chip 110 is mounted onto the upper surface of the interconnecting substrate 120 in a flip-chip configuration.

It can be realized that the first conductive lead 130 and the second conductive lead 140 in the packaging process are connected to each other by a tie bar of a lead frame (not shown). After the LED chip 110 has been encapsulated in a transparent molding material (not shown) by using transfer molding or glob-top process, the tie bar is cut so that the first conductive lead 130 and the second conductive lead 140 are separated from each other. The suitable lead frame of the present invention is generally made of alloy by using a copper as a primary material or formed with copper or copper alloy, and generally formed by punching or etching.

In one embodiment, the above-mentioned step of the flip-chip configuration comprises the following steps. The LED chip 110 is precisely disposed on a predetermined position of the upper surface of the interconnecting substrate 120 by using of a robot with the automatic putting and selecting. Therefore, the solder bump formed on the chip can precisely align the first conductive pad 121 and the second conductive pad 122 of the interconnecting substrate 120. Then, the solder joints 150a and 150b are formed by performing a reflow step so that the LED chip 110 is fixed on the interconnecting substrate 120 and electrically connected to the interconnecting substrate 120.

In one embodiment, the solder bump of the chip can be formed by using Controlled Collapse Chip Connection (C4) process and comprises the following steps. (A) A under bump metallurgy (UBM) is formed on the electrical contacts 115 and 116 of the LED chip 110. (B) A solder bump is formed on the UBM. In another embodiment, the solder bump can also be formed as a cylindrical shape solder bump by stencil printing.

In another embodiment, the solder bump formed on the chip can also be formed with the solder ball directly mounted onto the electrical contacts 115 and 116. In addition, a gold stud bump can also be replaced the solder bump formed on the LED chip 110. In this embodiment, the LED chip 110 is fixed on the interconnecting substrate 120 and electrically connected to the interconnecting substrate 120 by adhering the gold stud bump formed on the chip with the conductive plastic or performing a thermosonic bonding to the gold stud bump formed on the LED chip 110.

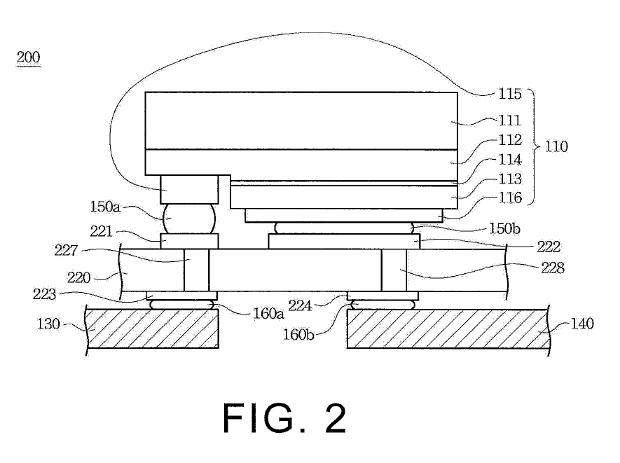

FIG. 2 is a schematic view of a light-emitting diode (LED) package structure 200. Only differences between a LED package structure 200 and the LED package structure 100 are described in the following, and the detailed description thereof is omitted.

Comparing with the LED package structure 100, a interconnecting substrate 220 of the LED package structure 200 is disposed between the LED chip 110 and the first conductive lead 130 and the second conductive lead 140

A first conductive pad 221 and a second conductive pad 222 are disposed on the upper surface of the interconnecting substrate 220. A third conductive pad 223 and a fourth conductive pad 224 are disposed on the lower surface of the interconnecting substrate 220 and electrically connected to first conductive pad 221 and the second conductive pad 222 by the above-mentioned plating through holes 227 and 228. A method of forming the plating through holes 227 and 228 is, for example, performing a mechanical drill process or a laser drill process. The position of the plating through holes 227 and 228 are corresponding to the first electrical contact 115 and the second electrical contact 116 of LED chip 110.

A material of the first conductive pad 221, the second conductive pad 222, the third conductive pad 223 and the fourth conductive pad 224 is, for example, copper. In addition, the surface of the conductive pad can also have a gold layer or a palladium layer.

The LED chip 110 as described above is flip chip bonded to the upper surface of the interconnecting substrate 120 by the metal joints 150a and 150b.

The first conductive lead 130 and the second conductive lead 140 as described above are respectively corresponding to the plating through holes 127 and 128 and soldered on the third conductive pad 223 and the fourth conductive pad 224 of the other side of the interconnecting substrate 120 by the solder joints 160a and 160b.

In the aforesaid embodiment, since the LED package structure of the present invention does not need to perform the wire bonding process to connect the LED and the substrate so as to save the wire bonding cost and does not need to reserve the wire space in the LED device. Therefore, the LED package structure can be applied to miniaturizing electronic products.

Although the present invention has been disclosed above by the embodiments, they are not intended to limit the present invention. Anybody skilled in the art can make some modifications and alterations without departing from the spirit and scope of the present invention. Therefore, the protecting range of the present invention falls in the appended claims.

What is claimed is:

1. A light-emitting diode (LED) package structure, comprising:
an interconnecting substrate having an upper surface and a lower surface;
a first conductive trace and a second conductive trace disposed on the upper surface of the interconnecting substrate;
a first conductive pad and a third conductive pad directly disposed on the first conductive trace and electrically connected to each other;
a second conductive pad and a fourth conductive pad directly disposed on the second conductive trace and electrically connected to each other;
a LED chip having a first electrical contact and a second electrical contact, wherein the LED chip is mounted onto the upper surface of the interconnecting substrate in a flip-chip configuration so that the first conductive contact and the second conductive contact are mechanically and electrically connected to the first electrical pad and the second electrical pad of the interconnecting substrate, respectively; and
a first conductive lead and a second conductive lead respectively soldered on the third conductive pad and the fourth conductive pad.

2. The LED package structure as claimed in claim 1, wherein the first electrical contact and the second electrical contact of the LED chip are mechanically and electrically connected to the first conductive pad and the second conductive pad of the interconnecting substrate via two metal joints, respectively.

3. The LED package structure as claimed in claim 1, wherein the LED chip comprises:
a substrate;
a first electrical semiconductor layer and a second electrical semiconductor layer located on the substrate and electrically connected to the first electrical contact and the second electrical contact, respectively; and
an active layer disposed between the first electrical semiconductor layer and the second electrical semiconductor layer.

4. The LED package structure as claimed in claim 1, wherein the reflectivity of the first electrical contact or the second electrical contact is at least 70%.

5. The LED package structure as claimed in claim 1, wherein the first electrical contact or the second electrical contact is selected from the group consisting of titanium, gold, aluminum, silver, platinum, palladium or a combination of alloys thereof.

6. The LED package structure as claimed in claim 1, wherein the material of the interconnecting substrate is selected from a group consisting of ceramic, aluminum oxide, aluminum nitride, silicon and gallium arsenide.

7. A light-emitting diode (LED) package structure, comprising:
an interconnecting substrate having an upper surface and a lower surface;
two plating through holes disposed in the interconnecting substrate;
a first conductive pad and a third conductive pad directly disposed in one of the plating through holes and electrically connected to each other;
a second conductive pad and a fourth conductive pad directly disposed in the other one of the plating through holes and electrically connected to each other;
a LED chip having a first electrical contact and a second contact, wherein the LED chip is mounted onto the upper surface of the interconnecting substrate in a flip-chip configuration so that the first conductive contact and the second conductive contact are mechanically and electrically connected to the first electrical pad and the second electrical pad of the interconnecting substrate, respectively; and
a first conductive lead and a second conductive lead respectively soldered on the third conductive pad and the fourth conductive pad.

8. The LED package structure as claimed in claim 7, wherein the first electrical contact and the second electrical contact of the LED chip are mechanically and electrically connected to the first conductive pad and the second conductive pad of the interconnecting substrate via two metal joints, respectively.

9. The LED package structure as claimed in claim 7, wherein the LED chip comprises:
a substrate;
a first electrical semiconductor layer and a second electrical semiconductor layer located on the substrate and electrically connected to the first electrical contact and the second electrical contact, respectively; and
an active layer disposed between the first electrical semiconductor layer and the second electrical semiconductor layer.

10. The LED package structure as claimed in claim 7, wherein the reflectivity of the first electrical contact or the second electrical contact is at least 70%.

11. The LED package structure as claimed in claim 7, wherein the first electrical contact or the second electrical contact is selected from the group consisting of titanium, gold, aluminum, silver, platinum, palladium or a combination of alloys thereof.

12. The LED package structure as claimed in claim 7, wherein the material of the interconnecting substrate is selected from a group consisting of ceramic, aluminum oxide, aluminum nitride, silicon and gallium arsenide.

13. A manufacturing method of a light-emitting diode (LED) package structure, comprising:
providing an interconnecting substrate having a first conductive pad, a second conductive pad, a third conductive pad and a fourth conductive pad, wherein the first conductive pad and the second conductive pad are electrically connected to the third conductive pad and the fourth conductive pad, respectively;
mounting a LED chip onto a upper surface of the interconnecting substrate in a flip-chip configuration so that a first conductive contact and a second conductive contact of the LED chip are mechanically and electrically connected to the first electrical pad and the second electrical pad of the interconnecting substrate, respectively; and
soldering a first conductive lead and a second conductive lead respectively on the third conductive pad and the fourth conductive pad.

14. The manufacturing method of the LED package structure as claimed in claim 13, wherein the first conductive pad, the second conductive pad, the third conductive pad and the fourth conductive pad are disposed on the upper surface of the interconnecting substrate.

15. The manufacturing method of the LED package structure as claimed in claim 13, wherein the first conductive pad and the second conductive pad are formed on the upper surface of the interconnecting substrate, and the third conductive pad and the fourth conductive pad are formed on a lower surface of the interconnecting substrate.

16. The manufacturing method of LED package structure as claimed in claim 13, wherein the material of the interconnecting substrate is selected from a group consisting of ceramic, aluminum oxide, aluminum nitride, silicon and gallium arsenide.

17. A light-emitting diode (LED) package structure, comprising:
an interconnecting substrate having a first conductive pad, a second conductive pad, a third conductive pad and a fourth conductive pad;
a first conductive trace and a second conductive trace disposed on the interconnecting substrate, wherein two ends of the first conductive trace are respectively served as the first conductive pad and the third conductive pad, and two ends of the second conductive trace are respectively served as the second conductive pad and the fourth conductive pad;
a LED chip having a first electrical contact and a second contact, wherein the LED chip is mounted onto the upper surface of the interconnecting substrate in a flip-chip configuration so that the first conductive contact and the second conductive contact are mechanically and electrically connected to the first electrical pad and the second electrical pad of the interconnecting substrate, respectively; and
a first conductive lead and a second conductive lead respectively soldered on the third conductive pad and the fourth conductive pad.

18. The LED package structure as claimed in claim 17, wherein the first electrical contact and the second electrical contact of the LED chip are mechanically and electrically connected to the first conductive pad and the second conductive pad of the interconnecting substrate via two metal joints.

19. The LED package structure as claimed in claim 17, wherein the reflectivity of the first electrical contact or the second electrical contact is at least 70%.
